(19) United States
(12) Patent Application Publication
(10) Pub. No.: US 2025/0110171 A1
(43) Pub. Date: Apr. 3, 2025

(54) CURRENT LIMIT TESTING SYSTEM FOR A TRANSISTOR

(71) Applicant: TEXAS INSTRUMENTS INCORPORATED, DALLAS, TX (US)

(72) Inventors: Abhinay PATIL, BANGALORE (IN); Vinayak HEGDE, BANGALORE (IN); Umang AGARWAL, BANGALORE (IN)

(21) Appl. No.: 18/677,217

(22) Filed: May 29, 2024

(30) Foreign Application Priority Data
Oct. 3, 2023 (IN) 202341066168

(51) Int. Cl. G01R 31/28; G01R 35/00

(52) U.S. Cl. CPC G01R 31/2834; G01R 35/005

(57) ABSTRACT

One example includes a circuit. The circuit includes a transistor device arranged between a first terminal and a second terminal and a transistor device controller configured to control operation of the transistor device. The circuit further includes a current limit controller that includes a current limit circuit configured to regulate an amplitude of operational current through the transistor device between the first and second terminals during a normal operating mode, and a testing system configured to conduct a calibration current provided by an automated testing equipment (ATE) device through an internal test resistor for the ATE device to determine a resistance value of the internal test resistor during a test mode to facilitate testing of the current limit circuit via a test current provided by the ATE device between the first and second terminals through the transistor device based on the determined resistance value of the internal test resistor.

### CROSS-REFERENCE TO RELATED APPLICATION

This application claims priority to India provisional patent application No. IN202341066168, filed Oct. 3, 2023, which is incorporated herein by reference in its entirety.

### TECHNICAL FIELD

This description relates to electronic circuits, and more specifically to a current limit testing system for a transistor device.

### BACKGROUND

Integrated circuits (ICs) are typically fabricated in bulk on a semiconductor wafer. Fabricated ICs undergo a variety of different operational tests using automated test equipment (ATE) device. For example, the ATE device can include contacts that implement current testing to determine limits on the operational current provided in different types of circuits, such as large transistor devices (e.g., power field-effect transistor devices (FETs)) that are configured to provide large power-providing currents. As an example, a large transistor device circuit may include current controls that can provide limits to current amplitudes, such as to mitigate damage or destruction of the circuit in response to excessive amplitudes of currents. In such circuits, the ATE device can perform tests not only on the operational capabilities of the circuit, but also on the current controls of the circuit to ensure proper operation of both the circuit and the safety features of the respective circuit.

### SUMMARY

One example includes a circuit. The circuit includes a transistor device arranged between a first terminal and a second terminal and a transistor device controller configured to control operation of the transistor device. The circuit further includes a current limit controller that includes a current limit circuit configured to regulate an amplitude of operational current through the transistor device between the first and second terminals during a normal operating mode, and a testing system configured to conduct a calibration current provided by an automated testing equipment (ATE) device through an internal test resistor for the ATE device to determine a resistance value of the internal test resistor during a test mode to facilitate testing of the current limit circuit via a test current provided by the ATE device between the first and second terminals through the transistor device based on the determined resistance value of the internal test resistor.

Another example includes a method for testing a current limit circuit of a device-under-test (DUT) circuit. The method includes coupling ATE device to a first terminal, a second terminal, and a third terminal of the DUT circuit and setting the DUT circuit to a test mode. The method also includes providing a calibration voltage to the third terminal to conduct a calibration current through an internal test resistor of the DUT circuit that is coupled to the third terminal to determine a resistance value of the internal test resistor. The method further includes providing a testing voltage across the first and second terminals to conduct a test current through a transistor device of the DUT circuit controlled by the current limit circuit based on the resistance value of the internal test resistor.

Another example includes a circuit test system. The system includes a DUT circuit that includes a transistor device arranged between a first terminal of the DUT circuit and a second terminal of the DUT circuit and a current limit controller comprising a current limit circuit configured to regulate an amplitude of operational current flowing through the transistor device between the first and second terminals. The current limit controller includes a testing system configured to conduct a calibration current through an internal test resistor during a first phase of a test mode and to conduct a portion of a test current through the internal test resistor during a second phase of the test mode. The test current can be provided between the first and second terminals through the transistor device. The circuit test system also includes ATE device coupled to the first, second, and third terminals. The ATE device can be configured to provide the calibration current via the first terminal through the internal test resistor during the first phase of the test mode to determine a resistance value of the internal test resistor, and to provide the test current through the transistor device between the first and second terminals to test functional operation of the current limit circuit based on the determined resistance value of the internal test resistor.

### BRIEF DESCRIPTION OF THE DRAWINGS

FIG. 1 is an example block diagram of a circuit test system.

FIG. 2 is an example diagram of a device-under-test (DUT) circuit.

FIG. 3 is an example of a timing diagram.

FIG. 4 is an example diagram of the DUT circuit in a test mode.

FIG. 5 is another example diagram of the DUT circuit in a test mode.

FIG. 6 is an example of a method for testing a current limit circuit of a DUT circuit.

### DETAILED DESCRIPTION

This description relates to electronic circuits, and more specifically to a current limit testing system for a transistor device. The system includes a device-under-test (DUT) circuit that includes a transistor device (e.g., a power field effect transistor device (FET)) and a current limit controller. As described in greater detail herein, the current limit controller can include a testing system that includes an internal test resistor to allow simplistic current limit testing of the current limit circuit. The testing system described herein can be implemented for accurate and low-cost testing of the current limit circuit.

The transistor device of the DUT circuit is configured to conduct an operational current between a first terminal and a second terminal during a normal operating mode. The current limit controller includes a current limit circuit. In response to the operational current increasing to a predefined amplitude, the current limit circuit is configured to regulate (e.g., cap or limit) the amplitude of the operational current during the normal operating mode. Therefore, the current limit circuit is configured to provide a measure of safety to protect the circuit from conducting too high of an amplitude of the operational current, thus mitigating damage or destruction of the transistor device and/or the circuit, as well as devices to which or from which the operational current is provided.

The predefined amplitude that defines the current threshold at which the current limit circuit activates can be set externally with respect to the integrated circuit (IC) corresponding to the DUT circuit in which the transistor device is fabricated. For example, the IC device can include a pin or contact to which an external limit resistor can be electrically coupled, thereby allowing the current threshold to be set based on the resistance value of the external resistor. However, the current limit circuit may require testing after fabrication of the circuit to ensure that the current limit circuit operates properly to limit the amplitude of the operational current in response to the operational current exceeding a predefined threshold. Absent such testing, the fabricated IC device may not be able to achieve certification of one or more industry standards.

The DUT circuit can be tested using any of a variety of conventional automated testing equipment (ATE) devices. However, because the predefined threshold can be set based on an external resistor, implementing ATE device for testing of the current limit circuit can be challenging. Some lower cost ATE devices may not include internal resistance settings or resistors on testing contacts to which the IC is coupled during testing. Such absence of testing contact resistance can prohibit testing of the current limit circuit. Some more sophisticated ATE devices can include internal resistors or resistive settings, thereby having the capability to simulate an external resistor to set the predefined threshold of the current limit circuit. However, such more sophisticated ATE devices can be significantly more expensive, thereby providing additional expense to the fabrication/testing process that can render the DUT more expensive. Additionally, regardless of the ATE device, the resistive contacts on ATE devices can introduce excessive parasitic effects (e.g., parasitic capacitance) on the IC device pin/contact, which can provide for instability in an associated control loop of the current limit circuit that can provide deleterious effects on the testing of the current limit circuit.

To provide for accurate testing of the current limit circuit using low cost ATE device, and thus absent resistive contacts on the ATE device, the current limit controller of the DUT circuit includes a testing system that is fabricated in the DUT circuit. The testing system includes an internal test resistor and a switch controller that can control the testing of the current limit circuit in a test mode. For example, the DUT circuit can be set to a test mode to facilitate testing of the DUT circuit via the ATE device. The ATE device can thus provide a calibration current through the internal test resistor, such that the ATE device can determine a resistance value of the internal test resistor. The resistance value of the internal test resistor can be nominally predefined during fabrication. However, due to process variations, the resistance value can vary greatly, such that determining the resistance value of the internal test resistor can provide for accurate test results. The ATE device can thus provide a test current through the transistor device to test the operation of the current limit circuit based on the determined resistance value of the internal test resistor.

As an example, the test mode can be implemented in a first phase and a second phase. The switch controller can control switches of the test system to provide the current flow of the calibration current through the internal test resistor during the first phase of the test mode to facilitate determination of the resistance value of the internal test resistor by the ATE device based on an amplitude of the calibration current. The switch controller can also control the switches to provide a limit current that is proportional to the test current through the internal test resistor during a second phase of the test mode to facilitate the test of the current limit circuit by the ATE device. Accordingly, the current limit circuit can be accurately and inexpensively tested (e.g., by a low cost ATE device) based on the simulation of the external resistor by the internal test resistor.

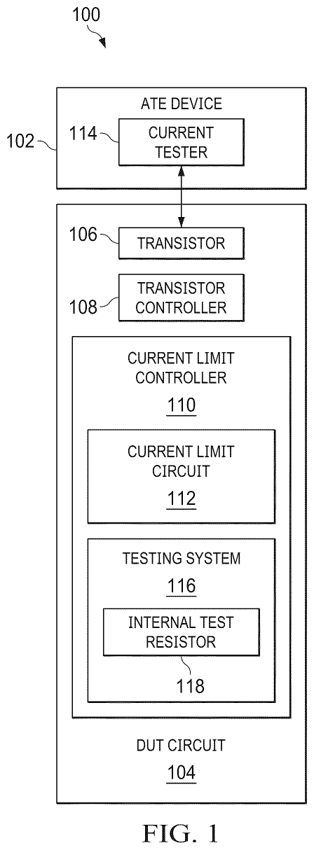

FIG. 1 is an example block diagram of a circuit test system 100. The circuit test system 100 includes an automated test equipment (ATE) device 102 that is configured to test one or more fabricated circuits, demonstrated in the example of FIG. 1 as a device-under-test (DUT) circuit 104. The ATE device 102 can be configured to provide circuit testing at wafer level or in the final test (FT) stage of the packaged DUT circuit 104, which can correspond to testing of the DUT circuit 104 after singulation and packaging of the DUT circuit 104 fabricated from a wafer. In the example of FIG. 1, the DUT circuit 104 includes a transistor device 106. As an example, the transistor device 106 can be a power field-effect transistor (FET) that can be implemented in or with a power supply circuit, such that the transistor device 106 can be configured to conduct a large amplitude of current (e.g., greater than 100A). The DUT circuit 104 also includes a transistor controller 108 that is configured to control operation of the transistor device 106 during normal operating conditions, such as via external transistor controls provided from a separate power supply control circuit.

The DUT circuit 104 also includes a current limit controller 110. The current limit controller 110 includes a current limit circuit 112 that is configured to activate in response to an operational current flowing through the transistor device 106 exceeding a predefined amplitude during a normal operating mode (e.g., normal operating conditions). As an example, the predefined amplitude can be defined by an external limit resistor that is electrically coupled to a limit pin or limit terminal of the DUT circuit 104, thereby allowing the current threshold associated with the predefined amplitude to be set based on the resistance value of the external limit resistor. In the example of FIG. 1, the ATE device 102 includes a current tester 114 configured to test the operation of the current limit circuit 112. As an example, the current tester 114 can provide a test current through the transistor device 106 to determine if the current limit circuit 112 operates to limit the current through the transistor device 106 in response to the test current increasing greater than the current threshold (e.g., by decreasing a gate voltage of the transistor device 106 via the transistor controller 108).

Because the predefined threshold of the current limit controller can be set in normal operating conditions based on an external limit resistor, the ATE device 102 may be required to simulate the external limit resistor for testing of the current limit circuit 110. For a typical testing environment, the ATE device 102 may not include internal resistance settings or resistors on the testing contacts that are coupled to the pins or contacts of a conventional DUT circuit, which can be nominally prohibitive of testing the current limit controller of a conventional DUT circuit. Additionally, the resistive contacts of the ATE device 102 could introduce excessive parasitic effects (e.g., parasitic capacitance) on the pin/contact of the conventional DUT circuit. The parasitic effects can provide for instability in an associated control loop of the current limit controller of the conventional DUT circuit that can provide deleterious effects on the testing of the respective current limit controller.

In the example of FIG. 1, the current limit controller 110 includes a testing system 116 that is fabricated in the DUT circuit 104. The testing system 116 includes an internal test resistor 118 that can simulate the external limit resistor that is electrically coupled to a limit pin or limit terminal of the DUT circuit 104 during normal operating conditions of the DUT circuit 104 to facilitate testing of the current limit circuit 110 by the current tester 114 of the ATE device 102. For example, the DUT circuit 104 can be set to a test mode (e.g., by the ATE device 102) to facilitate testing of the DUT circuit 104 via the ATE device 102. During the test mode, the internal test resistor 118 can be provided in a current path for a calibration current in a first phase of the test mode to determine a resistance value of the internal test resistor, and in a current path for a limit current that is proportional to the test current in a second phase of the test mode. As an example, the limit current can be provided as a portion of the test current, or can be a current that is generated separately but has an amplitude that is proportional to the test current. The ATE device 102 can thus provide the test current through the transistor device 106 to test the operation of the current limit circuit 112 based on conducting the limit current through the internal test resistor having the determined resistance value.

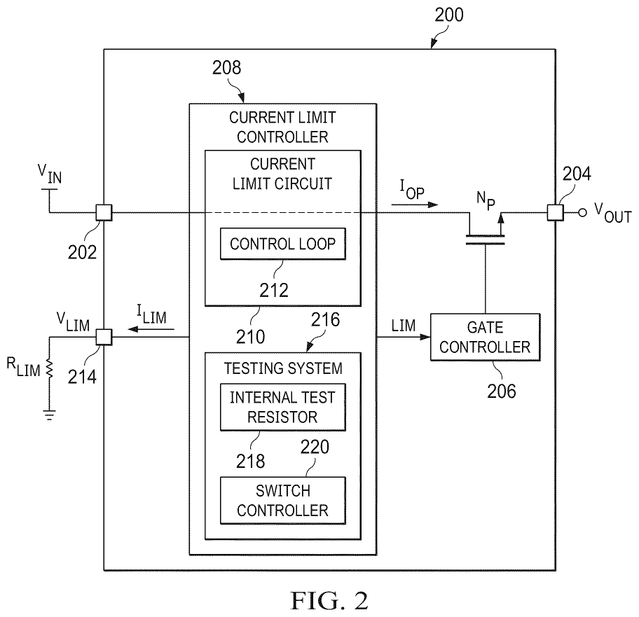

FIG. 2 is an example diagram of a DUT circuit 200. The DUT circuit 200 can correspond to the DUT circuit 104 in the example of FIG. 1. Therefore, reference is to be made to the example of FIG. 1 in the following description of the example of FIG. 2.

In the example of FIG. 2, the DUT circuit 200 is demonstrated in an arrangement that can correspond to a normal operating condition. The DUT circuit 200 includes a power FET Np, demonstrated as an N-type FET, that can correspond to the transistor device 106 in the example of FIG. 1. The power FET N_{P} is arranged between a first terminal 202 that is coupled to a drain of the power FET N_{P} and a second terminal 204 that is coupled to a source of the power FET N_{P}. The DUT circuit 200 also includes a gate controller 206 that is coupled to a gate of the power FET N_{P}, and can therefore correspond to the transistor controller 108 in the example of FIG. 1. The gate controller 206 is thus configured to control operation of the power FET in a normal operating mode to conduct an operational current I_{OP} from an input voltage V_{IN} provided at the first terminal 202 to provide an output (demonstrated as an output voltage V_{OUT}, such as across a load (not pictured)) at the second terminal 204.

The DUT circuit 200 also includes a current limit controller 208. The current limit controller 208 includes a current limit circuit 210 that is configured to activate in response to the operational current lop flowing through the transistor device power FET Np exceeding a current threshold during a normal operating mode. The current limit circuit 210 includes a control loop 212 that can conduct a limit current I_{LIM} through the current limit controller 208, with the limit current I_{LIM} being proportional to the amplitude of the operational current I_{OP}. Therefore, in response to the limit current I_{LIM} exceeding a predefined amplitude corresponding to the current threshold of the operational current I_{OP}, the current limit circuit 210 can activate to limit (e.g., cap or reduce) the amplitude of the operational current I_{OP}. In the example of FIG. 2, the current limit controller 208 is demonstrated as providing a signal LIM to the gate controller 206 in response to the limit current I_{LIM} exceeding the predefined amplitude, such that the gate controller 206 can control the power FET N_{P} to limit the amplitude of the operational current I_{OP}. As an example, the power FET N_{P} can operate in linear mode during normal operating conditions, such that, when the current limit circuit 210 activates, the signal LIM can reduce the gate voltage of the power FET N_{P} to operate the power FET N_{P} in saturation mode to limit the amplitude of the operational current I_{OP}.

In the example of FIG. 2, the current threshold of the current limit circuit 210 is defined by an external limit resistor R_{LIM} that is electrically coupled to a limit terminal 214 of the DUT circuit 200. The current I_{PROP} can be provided through the external limit resistor R_{LIM} to provide a voltage V_{LIM} at the limit terminal 214. As an example, the limit terminal 214 can correspond to a third terminal of the DUT circuit 200, such as a pin, pad, or other external contact. The amplitude of the limit voltage V_{LIM}, as provided by the resistance value of the external limit resistor R_{LIM}, can thus be proportional to or related to the current threshold of the operational current I_{OP}.

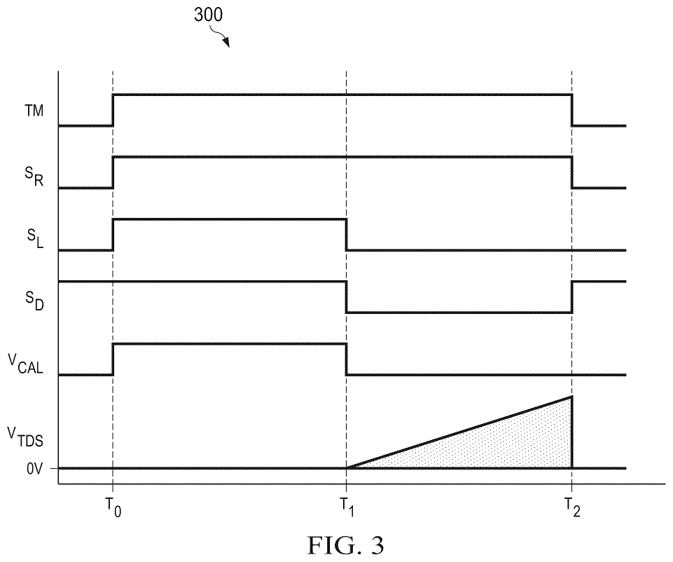

As described in the example of FIG. 2, the current limit controller 208 includes a testing system 216 that can facilitate testing of the current limit circuit 208, such as by the ATE device 102. The testing system 216 includes an internal test resistor 218 and a switch controller 220. The internal test resistor 218 can simulate the external limit resistor R_{LIM} during the testing of the current limit circuit 208. The switch controller 220 can operate a plurality of switches during the test mode to conduct a calibration current through the internal test resistor 218 to determine an actual resistance value of the internal test resistor 218, and to conduct a portion of a test current, having the same proportionality as the current I_{PROP} relative to the operational current I_{OP}, through the internal test resistor 218 to test the operation of the current limit circuit 210. As described in greater detail in the examples of FIGS. 3-5, the test mode can be provided in two phases.

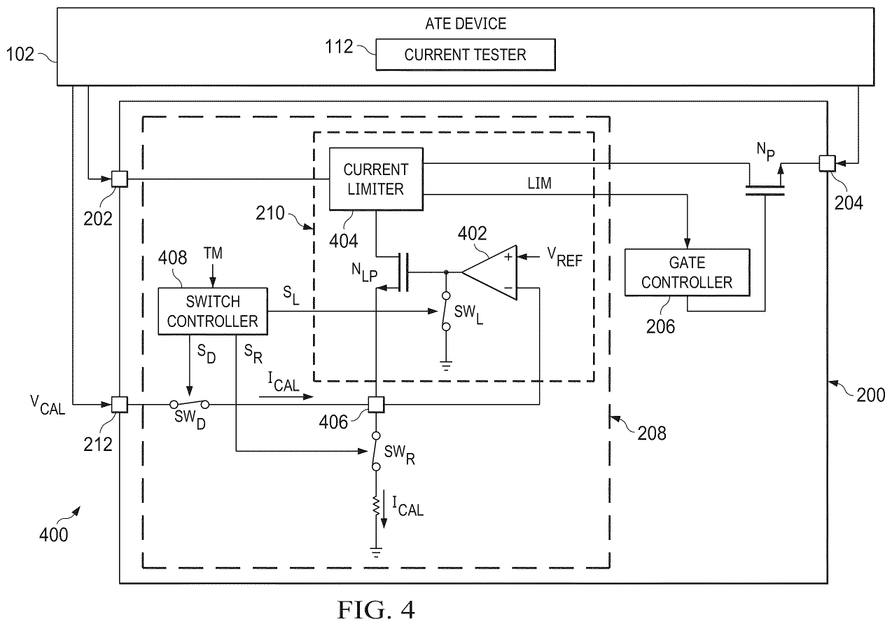

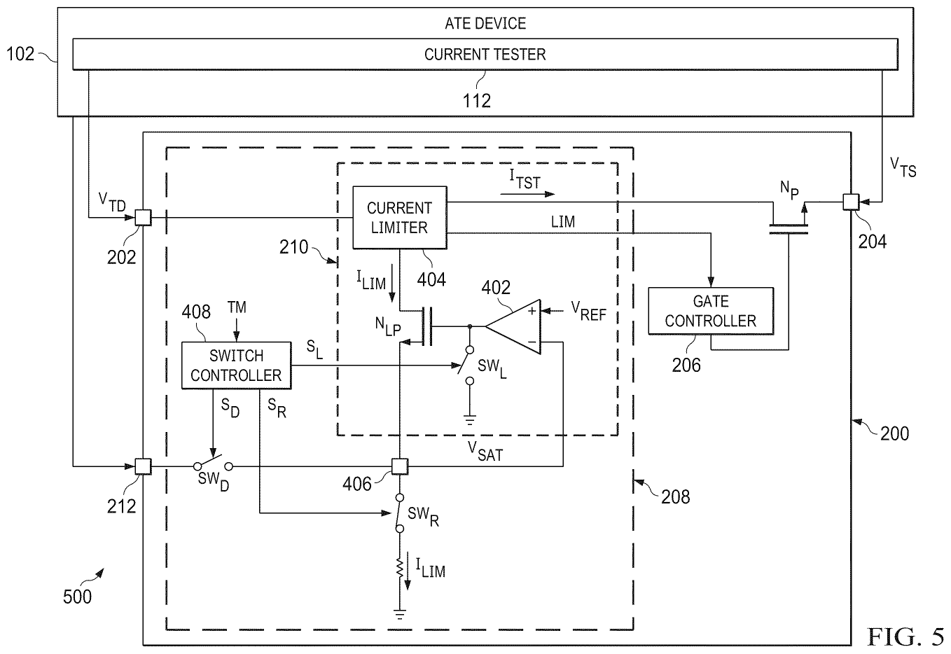

FIG. 3 is an example of a timing diagram 300. FIG. 4 is an example diagram 400 of the DUT circuit 200 in a first phase of the test mode. FIG. 5 is an example diagram 500 of the DUT circuit 200 in a second phase of the test mode. In the examples of each of FIGS. 4 and 5, reference is to be made to the timing diagram 300 in the example of FIG. 3. Furthermore, reference is to be made to the examples of FIGS. 1 and 2 in the following description of the examples of FIGS. 3-5.

The diagram 400 includes the DUT circuit 200 and the ATE device 102. The ATE device 102 is demonstrated as being electrically coupled to each of the first terminal 202, the second terminal 204, and the limit terminal 214. In each of the examples of FIGS. 4 and 5, the DUT circuit 200 includes the power FET N_{P}, the gate controller 206, and the current limit controller 208. The current limit controller 208 includes the current limit circuit 210. The current limit circuit 210 includes a control loop transistor N_{LP}, demonstrated as N-type FET, and a control loop amplifier 402 that collectively correspond to the control loop 212. The current limit circuit 210 also includes a current limiter 404 that is arranged between the first and second terminals 202 and 204. The control loop transistor NLP has a drain coupled to the current limiter 404, and has a source coupled to a control loop terminal 406. The control loop amplifier 402 has a first input that receives a reference voltage V_{REF} and a second input that is coupled to the control loop terminal 406. The control loop amplifier 402 has an output that is coupled to the gate of the control loop transistor N_{LP}, such that the control loop amplifier 402 controls the operation of the control loop transistor N_{LP}.

The current limit controller 208 also includes an internal test resistor R_{IT} and a switch controller (“SC”) 408 that is configured to control a first switch SW_{R} via a first switching signal S_{R}, a second switch SW_{L}. via a second switching signal S_{L}, and a third switch SW_{D} via a third switching signal S_{D}. The first switch SW_{R} interconnects the control loop terminal 406 and the internal test resistor R_{IT}. The second switch SW_{L}. interconnects the output of the control loop amplifier 402 and a low-voltage rail (e.g., ground). The third switch SW_{D} interconnects the limit terminal 214 and the control loop terminal 406. The internal test resistor R_{IT}, the switch controller 408, and the switches SW_{R}, SW_{L}, and SW_{D}, as well as the interconnections therebetween, correspond collectively to the testing system 216.

The timing diagram 300 includes a test mode signal TM that corresponds to the test mode. In the example of FIGS. 4 and 5, the test mode signal TM is provided to the switch controller 408 to indicate the beginning of the test mode. As an example, the test mode signal TM can be provided externally from the ATE device 102, such as based on being provided to a dedicated contact/pin or a multifunctional contact/pin. Any of a variety of control mechanisms can be implemented to set the DUT circuit 200 to the test mode. With reference to the timing diagram 300, the test mode signal TM is asserted at a time T₀ to set the DUT circuit 200 to the test mode to initiate testing of the current limit circuit 208. As described above, the test mode can be divided into a first phase and a second phase. In the example of FIG. 3, the first phase of the test mode is provided from the time T₀ to a time T₁, and is represented by the diagram 400 in the example of FIG. 4. The second phase of the test mode is provided from the time T₁ to a time T₂, and is represented by the diagram 500 in the example of FIG. 5. The timing of each of the first and second phases can be based on time division (e.g., preset time durations), or can be based on multiple states of the test mode signal TM as provided by the ATE device 102, rather than the binary states demonstrated in the example of FIG. 3.

At the time T₀, and thus at the beginning of the first phase of the test mode, the first switching signal S_{R} and the second switching signal S_{L}, are asserted to close the first and second switches SW_{R} and SW_{L}, respectively. The third switch SW_{D} can be closed during a normal operating mode, and thus the third switching signal S_{D} is demonstrated in the example of FIG. 3 as being asserted prior to the time T₀. Therefore, the third switch SW_{D} can be provided in a closed state at the time T₀ via the third switching signal S_{D} provided by the switch controller 408. Based on the state of the switching signal S_{R}, the first switch SW_{R} electrically couples the internal test resistor R_{IT} to the control loop terminal 406. Based on the state of the switching signal S_{L}, the second switch SW_{L}, electrically couples the output of the control loop amplifier 402 to the low-voltage rail. Based on the state of the switching signal S_{D}, the third switch SW_{D} electrically couples the limit terminal 214 to the control loop terminal 406.

At or shortly after the time T₀, as demonstrated in the example of FIG. 3, the current tester 114 of the ATE device 102 provides a calibration voltage V_{CAL} to the limit terminal 214. The calibration voltage V_{CAL} can be provided at a precise predefined amplitude. Based on the closed state of the switches SW_{D} and SW_{R}, the calibration voltage V_{CAL} can provide a calibration current I_{CAL} from the limit terminal 214 through the internal test resistor R_{IT}. Because of the closed state of the third switch SW_{L}, the control loop transistor N_{LP} can be disabled based on being held in a deactivated (e.g., cutoff) state, thereby disabling the control loop 212 to force the entirety of the calibration current I_{CAL} through the internal test resistor R_{IT}. Based on the predefined precise amplitude of the calibration voltage V_{CAL}, the ATE device 102 can determine the actual resistance value of the internal test resistor R_{IT}, as opposed to a nominal resistance value at which the internal test resistor R_{IT} is fabricated in the DUT circuit 200. The ATE device 102 can thus store the actual resistance value of the internal test resistor R_{IT} in a memory (not shown).

At the time T₁, and thus at the beginning of the second phase of the test mode, the first switching signal S_{R} remains asserted to hold the first switch SW_{R} in a closed state. The second and third switching signals S_{L} and S_{D} can be de-asserted to open the second and third switches SW_{L} and SW_{D}, respectively. Based on the state of the switching signal S_{R}, the first switch SW_{R} continues to electrically couple the internal test resistor R_{IT} to the control loop terminal 406. Based on the state of the switching signal S_{L}, the second switch SW_{L}, electrically decouples the output of the control loop amplifier 402 from the low-voltage rail. Based on the state of the switching signal S_{D}, the third switch SW_{D} electrically decouples the limit terminal 214 from the control loop terminal 406. The current tester 114 of the ATE device 102 can also stop providing the calibration voltage V_{CAL} at the time T₀.

At or shortly after the time T₀, the current tester 114 of the ATE device 102 provides a drain test voltage V_{TD} to the first terminal 202 of the DUT circuit 200 and a source test voltage V_{TS} to the second terminal 204 of the DUT circuit 200. The calibration voltage V_{CAL} can be provided at a precise predefined amplitude. In the example of FIG. 3, the drain test voltage V_{TD} and the source test voltage V_{TS} can be provided at precise amplitudes, and are demonstrated as a voltage V_{TDS} corresponding to a drain-source voltage V_{DS} across the power FET N_{P}. Therefore, the drain test voltage V_{TD} and the source test voltage V_{TS} can provide a test current I_{TST} having a precise amplitude between the first and second terminals 202 and 204 and through the power FET N_{P}. The voltage V_{TDS} is demonstrated in the example of FIG. 3 as being variable (e.g., steadily increasing) to dynamically change the amplitude of the test current I_{TST} in a precise and controlled manner to test the operation of the current limit controller 208.

Based on the open state of the switch SW_{D}, the limit terminal 214 is electrically decoupled from the control loop terminal 406 in the second phase of the test mode, and based on the open state of the switch SW_{L}, the output of the control loop amplifier 402 is electrically decoupled from the low-voltage rail in the second phase of the test mode. The electrical decoupling of the limit terminal 214 from the control loop terminal 406 thus mitigates the presence of parasitic capacitance provided by the ATE device 102 from providing instability in the control loop 212, and thus negatively affecting the test of the current limit circuit 210. Based on the closed state of the switch SW_{R}, the internal test resistor R_{IT} remains electrically coupled to the control loop terminal 406 in the second phase of the test mode. Therefore, the control loop 212 is activated to conduct a limit current I_{LIM} from the current limiter 404 through the control loop transistor N_{LP} and through the internal test resistor R_{IT}. Similar to as described above, the limit current I_{LIM} can have an amplitude that is proportional to the test current I_{TST}. Therefore, the ATE device 102 can determine an amplitude of the test current I_{TST} at which the current threshold defined by the internal test resistor R_{IT} is achieved to activate the current limit controller 208 to limit the amplitude of the test current I_{TST}.

Because the nominal resistance value of the internal test resistor R_{IT} and the actual resistance value of the internal test resistor R_{IT} are both identified in the second phase of the test mode, the ATE device 102 can compare the amplitude of the nominal resistance value of the internal test resistor R_{IT} and the actual resistance value of the internal test resistor R_{IT} to determine an error value. The ATE device 102 can thus determine that the current limit controller 208 passes the current limit test in response to the amplitude of the test current I_{TST} at which the current limit controller 208 activates being within an acceptable amplitude range, as modified by the error value. In the example of FIG. 5, the signal LIM that is provided from the current limiter 404 to the gate controller 206. However, any of a variety of other mechanisms for indicating that the test current I_{TST} has achieved the current threshold can be implemented to signal activation of the current limit controller 208 to the gate controller 206.

At the time T₂, the test mode signal TM is de-asserted, thereby concluding the test mode. Therefore, at the time T₂, the first switching signal S_{R} is de-asserted to open the first switch SW_{R}, the second switching signal S_{L} remains de-asserted to maintain the open state of the second switch SW_{L}, and the third switching signal S_{D} is re-asserted to close the third switch SW_{D}. Therefore, the DUT circuit 200 is returned to the normal operating condition to facilitate operation of the current limit controller 208 based on electrically coupling the external limit resistor R_{LIM} to the limit terminal 214.

As a result of the testing system described herein, the current limit controller 208 of the DUT circuit 200 can be tested by an ATE device that does not include resistors or resistive contacts, thereby allowing testing of the current limit circuit 208 of the DUT circuit 200 via a low cost conventional ATE device. Further, the testing of the current limit circuit 208 of the DUT circuit 200 can be performed without loading parasitic effects (e.g., parasitic capacitance) on the limit terminal 214 to provide for rapid and accurate testing.

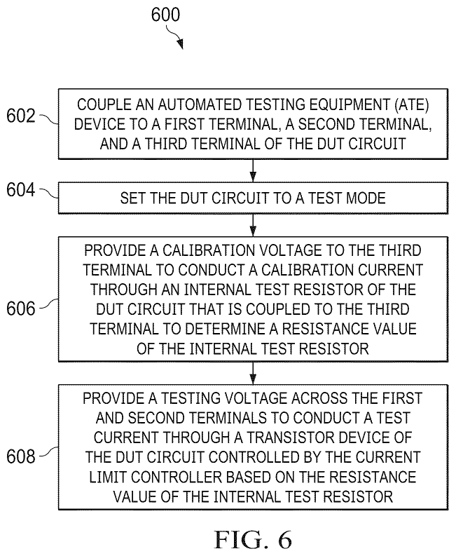

In view of the foregoing structural and functional features described above, methodologies in various aspects of the description will be better appreciated with reference to FIG. 6. The method of FIG. 6 is not limited by the illustrated order, as some aspects could, in the present description, occur in different orders and/or concurrently with other aspects from that shown and described herein. Moreover, not all illustrated features may be required to implement methodologies in an aspect of the present examples.

FIG. 6 is an example of a method 600 for testing a current limit controller (e.g., the current limit controller 110) of a DUT circuit (e.g., the DUT circuit 104). At 602, an ATE device (e.g., the ATE device 102) is coupled to a first terminal (e.g., the first terminal 202), a second terminal (e.g., the second terminal 204), and a third terminal (e.g., the limit terminal 214) of the DUT circuit. At 604, the DUT circuit is set to a test mode. At 606, a calibration voltage (e.g., the calibration voltage V_{CAL}) is provided to the first terminal to conduct a calibration current (e.g., the calibration current I_{CAL}) through an internal test resistor (e.g., the internal test resistor 118) of the DUT circuit that is coupled to the third terminal to determine a resistance value of the internal test resistor. At 608, a testing voltage (e.g., the voltage V_{TDS}) is provided across the first and second terminals to conduct a test current (e.g., the test current I_{TST}) through a transistor device (e.g., the transistor device 106) of the DUT circuit controlled by the current limit controller based on the resistance value of the internal test resistor.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

In this description, the term “couple” can cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, a device that is “configured to” perform a task or function can be configured (e.g., programmed and/or hardwired) at a time of manufacturing by a manufacturer to perform the function and/or can be configurable (or reconfigurable) by a user after manufacturing to perform the function and/or other additional or alternative functions. The configuring can be through firmware and/or software programming of the device, through a construction and/or layout of hardware components and interconnections of the device, or a combination thereof. Furthermore, a circuit or device that is described herein as including certain components can instead be configured to couple to those components to form the described circuitry or device. For example, a structure described herein as including one or more semiconductor elements (such as transistor devices), one or more passive elements (such as resistors, capacitors, and/or inductors), and/or one or more sources (such as voltage and/or current sources) can instead include only the semiconductor elements within a single physical device (e.g., a semiconductor die and/or integrated circuit (IC) package) and can be configured to couple to at least some of the passive elements and/or the sources to form the described structure, either at a time of manufacture or after a time of manufacture, such as by an end-user and/or a third-party.

The phrase “based on” means “based at least in part on”. Therefore, if X is based on Y, X can be a function of Y and any number of other factors.

Modifications are possible in the described embodiments, and other embodiments are possible, within the scope of the claims.

What is claimed is:

1. A circuit comprising:
a transistor device arranged between a first terminal and a second terminal;
a transistor device controller configured to control operation of the transistor device; and
a current limit controller comprising a current limit circuit configured to regulate an amplitude of operational current through the transistor device between the first and second terminals during a normal operating mode, and further comprising a testing system configured to conduct a calibration current provided by an automated testing equipment (ATE) device through an internal test resistor for the ATE device to determine a resistance value of the internal test resistor during a test mode to facilitate testing of the current limit circuit via a test current provided by the ATE device between the first and second terminals through the transistor device based on the determined resistance value of the internal test resistor.

2. The circuit of claim 1, wherein the current limit controller is coupled to a third terminal that is adapted to receive an external resistor to set a threshold for the amplitude of the operational current at which the current limit circuit is activated during the normal operating mode, wherein the testing system is configured to conduct the calibration current from the ATE device through the internal test resistor via the third terminal.

3. The circuit of claim 1, wherein the testing system is configured to facilitate the testing of the current limit circuit by conducting a limit current that is proportional to the test current through the internal test resistor after determining the resistance value of the internal test resistor.

4. The circuit of claim 3, wherein the testing system comprises a switch controller configured to provide a plurality of switching signals to control a respective plurality of switches during the test mode to facilitate conduction of the calibration current through the internal test resistor and to facilitate conduction of the limit current through the internal test resistor during the test mode.

5. The circuit of claim 4, wherein the current limit circuit comprises:
a current limiter arranged between the first and second terminals of the circuit and being configured to provide the limit current;
a control loop transistor device coupled between the current limiter and a control loop terminal, the control loop terminal being selectively coupled to the internal test resistor via one of the switches and being coupled to a third terminal of the circuit that is adapted to receive an external resistor to set a threshold for the amplitude of the operational current at which the current limit circuit is activated during the normal operating mode, the control loop transistor device being configured to conduct the limit current from the current limiter; and
a control loop amplifier configured to control the control loop transistor device based on a reference voltage.

6. The circuit of claim 5, wherein the testing system further comprises:
a first switch corresponding to the respective one of the switches arranged between the internal test resistor and the control loop terminal;
a second switch arranged between the control loop terminal and the third terminal; and
a third switch arranged between an output of the control loop amplifier and a low-voltage rail

7. The circuit of claim 6, wherein the first, second, and third switches are closed during a first phase of the test mode to provide a current path for the calibration current provided by the ATE device from the third terminal through the internal test resistor to the low-voltage rail via the first and second switches during the first phase of the test mode, and to disable the control loop amplifier via the third switch during the first phase of the test mode to determine the resistance value of the internal test resistor,
wherein the ATE device is configured to provide predefined voltages to the first and second terminals of the circuit to conduct the test current through the transistor device during a second phase of the test mode, wherein the second switch and the third switches are each opened during the second phase of the test mode to conduct the limit current through the internal test resistor via the second switch and to enable the control loop amplifier via the third switch to facilitate the testing of the current limit circuit during the second phase of the test mode.

8. The circuit of claim 1, wherein the test mode comprises:
a first phase during which the testing system conducts the calibration current provided by the ATE device through the internal test resistor for the ATE device to determine the resistance value of the internal test resistor; and
a second phase subsequent to the first phase during which the ATE device provides predefined voltages to each of the first and second terminals to provide the test current through the transistor device to test the current limit circuit based on the determined resistance value of the internal test resistor.

9. The circuit of claim 8, wherein the testing system comprises:
a plurality of switches configured to conduct the calibration current through the internal test resistor in the first phase of the test mode and to conduct a limit current through the internal test resistor in the second phase of the test mode; and
a switch controller configured to control operation of the switches during each of the first and second phases of the test mode.

10. The circuit of claim 9, wherein the current limit circuit comprises:
a control loop transistor device coupled between the first terminal of the circuit and a control loop terminal, the control loop terminal being selectively coupled to the internal test resistor via a first one of the switches and selectively coupled to a third terminal of the circuit via a second one of the switches, the third terminal being adapted to receive an external resistor to set a threshold for the amplitude of the operational current at which the current limit circuit is activated during the normal operating mode, the control loop transistor device being configured to conduct the limit current during the second phase of the test mode; and
a control loop amplifier configured to control the control loop transistor device based on a reference voltage, the control loop amplifier having an output that that is selectively coupled to a low-voltage rail by a third one of the switches.

11. A method for testing a current limit circuit of a device-under-test (DUT) circuit, the method comprising:
coupling an automated testing equipment (ATE) device to a first terminal, a second terminal, and a third terminal of the DUT circuit;
setting the DUT circuit to a test mode;
providing a calibration voltage to the third terminal to conduct a calibration current through an internal test resistor of the DUT circuit that is coupled to the third terminal to determine a resistance value of the internal test resistor; and
providing a testing voltage across the first and second terminals to conduct a test current through a transistor device of the DUT circuit controlled by the current limit circuit based on the resistance value of the internal test resistor.

12. The method of claim 11, wherein the current limit circuit comprises:
a current limiter arranged between the first and second terminals of the circuit and being configured to provide a limit current that is proportional to the test current;
a control loop transistor device coupled between the current limiter and a control loop terminal and configured to conduct the limit current; and
a control loop amplifier configured to control the control loop transistor device based on a voltage of the control loop terminal and a reference voltage.

13. The method of claim 12, wherein setting the DUT circuit to the test mode comprises:
controlling a plurality of switches in a first phase of the test mode to deactivate the control loop transistor device and to conduct the calibration current through the internal test resistor to determine the resistance value of the internal test resistor; and
controlling the switches in a second phase of the test mode to activate the control loop transistor device and to conduct the limit current through the control loop transistor device and through the internal test resistor to test the current limit circuit.

14. The method of claim 13, wherein controlling the switches in the first phase of the test mode comprises:
closing a first switch arranged between the internal test resistor and the control loop terminal;
providing a closed state of a second switch arranged between the control loop terminal and the third terminal; and
closing a third switch arranged between an output of the control loop amplifier and a low- voltage rail,
wherein controlling the switches in the second phase of the test mode comprises:
providing a closed state of the first switch;
opening the second switch; and
opening the third switch.

15. The method of claim 13, further comprising:
comparing the resistance value of the internal test resistor with a theoretical resistance value of the internal test resistor to determine an error value;
determining an amplitude of the test current at which the current limit circuit activates to limit an amplitude of operational current flowing through the transistor device; and
determining that the current limit circuit passes the testing in response to the amplitude of the test current at which the current limit circuit activates to limit the amplitude of the operational current flowing through the transistor device is within an acceptable amplitude range, as modified by the error value.

16. A current testing system comprising:
a device-under-test (DUT) circuit comprising:
a transistor device arranged between a first terminal of the DUT circuit and a second terminal of the DUT circuit; and
a current limit controller comprising a current limit circuit configured to regulate an amplitude of operational current flowing through the transistor device between the first and second terminals, the current limit controller comprising a testing system configured to conduct a calibration current through an internal test resistor during a first phase of a test mode and to conduct a limit current that is proportional to a test current through the internal test resistor during a second phase of the test mode, the test current being provided between the first and second terminals through the transistor device; and
an automated testing equipment (ATE) device coupled to the first, second, and third terminals, the ATE device being configured to provide the calibration current via the first terminal through the internal test resistor during the first phase of the test mode to determine a resistance value of the internal test resistor, and to provide the test current through the transistor device between the first and second terminals to test functional operation of the current limit circuit based on the determined resistance value of the internal test resistor.

17. The circuit of claim 16, wherein the testing system comprises a switch controller configured to provide a plurality of switching signals to control a respective plurality of switches during the test mode to facilitate conduction of the calibration current through the internal test resistor and to facilitate conduction of the limit current through the internal test resistor during the test mode.

18. The circuit of claim 17, wherein the current limit circuit comprises:
a current limiter arranged between the first and second terminals of the circuit and being configured to provide the limit current;
a control loop transistor device coupled between the current limiter and a control loop terminal, the control loop terminal being selectively coupled to the internal test resistor via one of the switches and being coupled to a third terminal of the circuit that is adapted to receive an external resistor to set a threshold for the amplitude of the operational current at which the current limit circuit is activated during a normal operating mode, the control loop transistor device being configured to conduct the limit current; and
a control loop amplifier configured to control the control loop transistor device based on a reference voltage.

19. The circuit of claim 18, wherein the testing system further comprises:
a first switch corresponding to the respective one of the switches arranged between the internal test resistor and the control loop terminal;
a second switch arranged between the control loop terminal and the third terminal; and
a third switch arranged between an output of the control loop amplifier and a low-voltage rail

20. The circuit of claim 19, wherein the first, second, and third switches are closed during a first phase of the test mode to provide a current path for the calibration current provided by the ATE device from the third terminal through the internal test resistor to the low-voltage rail via the first and second switches during the first phase of the test mode, and to disable the control loop amplifier via the third switch during the first phase of the test mode to determine the resistance value of the internal test resistor,
wherein the ATE device is configured to provide predefined voltages to the first and second terminals of the circuit to conduct the test current through the transistor device during a second phase of the test mode, wherein the second switch and the third switches are each opened during the second phase of the test mode to conduct the limit current through the internal test resistor via the second switch and to enable the control loop amplifier via the third switch to facilitate the testing of the current limit circuit during the second phase of the test mode.
